(19) United States
(12) Patent Application Publication
(10) Pub. No.: US 2007/0032090 A1
(43) Pub. Date: Feb. 8, 2007

(54) Plasma rapid thermal process apparatus in which supply part of radical source is improved

(75) Inventors: Sung Soo Si, Seoul (KR); Seong Tae Kim, Suwon-si (KR); Seok Jeong Lee, Seoul (KR); Kang Heum Yeon, Suwon-si (KR); Dae Seok Song, Anyang-si (KR)

Correspondence Address: IPLA P.A., 3580 WILSHIRE BLVD., 17TH FLOOR, LOS ANGELES, CA, 90010, US

(73) Assignee: KORNIC SYSTEMS CORP., Hwaseong-si (KR)

(21) Appl. No.: 10/595,203

(22) PCT Filed: Sep. 17, 2004
(86) PCT No.: PCT/KR04/02384

§ 371 Date: Mar. 23, 2006

(30) Foreign Application Priority Data
Sep. 26, 2003 (KR) 10-2003-0066950

(51) Int. Cl. H01L 21/302; H01L 21/461

(52) U.S. Cl. 438/758; 438/729

(57) ABSTRACT

Disclosed is a plasma rapid thermal process apparatus having an improved plasma supply port for supplying atomic radicals to a rapid thermal process chamber. The supply port includes an inner tube and an outer tube. The inner tube has one end which is opened and connected to the discharge tube and the other end which is closed. The diameter of a closed portion of the other end is smaller than those of other portions of the other end. A first spray hole is formed around a side wall of the closed portion. The outer tube has one end which is opened such that the closed portion of the inner tube is inserted in the one end, and the other end at which a plurality of second spray holes is formed. The other end of the outer tube is spaced apart by a predetermined interval from the other closed end of the inner tube. With the improved supply port, it is possible to achieve a highly efficient and uniform thermal process with low thermal budget at low temperature.

### TECHNICAL FIELD

The present invention relates to a plasma rapid thermal process apparatus, and more particularly to a plasma rapid thermal process apparatus having an improved plasma supply port in a rapid thermal process chamber.

### Background Art

Conventional techniques have a limitation in their ability to decrease the thickness of a dielectric film or increase an effective cross sectional area thereof to secure effective capacitance required to operate an ultra large scale integrated memory device. To overcome this limitation, an increasing interest is being taking in techniques using Ta₂O₅, TaON, (Ba,Sr)TiO₃, SrTiO₃, BaTiO₃, Pb(Zr,Ti)O₃, (Pb,La)(Zr,Ti)O₃, etc., which have high dielectric constants, as a capacitor dielectric film, and using noble metal such as Pt, Ru, Ir, PtO, RuO₂, IrO₂, SrRuO₃, BaSrRuO₃, and LaScCo as an electrode.

To this end, a thermal process apparatus is required which allows a process of a low thermal budget and a highly efficient and uniform thermal process at low temperature so that an effect on an interface between the electrode and the dielectric film having a high dielectric constant can be minimized.

However, in fabricating an ultra large scale integrated memory MIM (Metal-Insulator-Metal) capacitor, it is difficult for conventional furnaces or rapid thermal process apparatuses not only to satisfy low thermal budget requirements required for improvement of mechanical/electrical characteristics of the noble metal electrode and the dielectric film having a high dielectric constant, antioxidation of an electrode surface, improvement of morphology of a dielectric film surface, and crystallization and curing of non-crystalline dielectric having a high dielectric constant, but also to achieve a highly efficient and uniform thermal process at low temperature.

### DISCLOSURE

[Technical Problem]

Therefore, the present invention has been made in view of the above problems, and it is an object of the present invention to provide a plasma rapid thermal process apparatus having an improved plasma supply port in a rapid thermal process chamber, which is capable of achieving a highly efficient and uniform thermal process at low temperature with low thermal budget.

[Technical Solution]

In accordance with an aspect of the present invention, the above and other objects can be accomplished by the provision of a plasma rapid thermal process apparatus comprising a chamber having a supply port and an exhaust port provided at both ends thereof, with a wafer being mounted in the chamber, a thermal source provided in the chamber and including a plurality of lamps for heating the wafer, a gas supply module for supplying process gas, a discharge tube for plasmalizing the process gas supplied from the gas supply module, and a microwave supply apparatus for supplying microwaves to the discharge tube,

wherein the supply port supplies atomic radicals to the chamber, the radicals being formed by the plasmalization of the process gas in the discharge tube, and

wherein the supply port includes:

an inner tube having one end which is opened and connected to the discharge tube and the other end which is closed, the diameter of a closed portion of the other end being smaller than those of other portions of the other end, and a first spray hole being formed around a side wall of the closed portion; and

an outer tube having one end which is opened such that the closed portion of the inner tube is inserted in the one end, and the other end at which a plurality of second spray holes is formed, the other end of the outer tube being spaced apart by a predetermined interval from the other closed end of the inner tube.

Preferably, the supply port and the exhaust port are arranged at side walls of the chamber, the inside of the chamber is symmetrical on the basis of a virtual line connecting the supply port and the exhaust port, and the bottom of the chamber is formed in parallel with the wafer.

Preferably, a heating apparatus is arranged around the supply port.

Preferably, the inner and outer tubes of the supply port are made of quartz, Teflon, alumina, aluminum 6061, SST 304, or Hastelloy C-22, or inner surfaces of the inner and outer tubes are coated with Teflon.

Preferably, the length of the supply port is greater than the thickness of the side wall of the chamber and is less than 100 mm.

Preferably, the inner diameter of the supply port is 15 to 25 mm.

Preferably, at least two supply ports and at least two exhaust ports are oppositely arranged in a one-to-one correspondence in the chamber, and at least one supply port is connected to the plasma supply apparatus.

Preferably, an exhaust plate on which a cooling water path is formed is arranged on a side wall opposite to the side wall on which the supply port is provided, a wafer transfer port and the exhaust port being arranged at the exhaust plate 180.

Preferably, the lamps of the thermal source are provided to emit light in a downward direction of the lamps and the supply port is arranged such that the process gas in the radical state is sprayed in parallel with the wafer within the chamber, and the lamps and the supply port are arranged such that a radiation region of light emitted from the lamps and a spray region of the process gas coincide with each other above the wafer.

Preferably, a discharge pressure control valve and a vacuum pump are arranged at the exhaust port.

Preferably, a spray angle of the supply port is formed such that the spray region of atomic radicals supplied through the supply port covers the entire wafer.

[Advantageous Effects]

According to the present invention, since activated atomic species in a radical state are used as a process source, it is possible to achieve a thermal process with low thermal budget. In addition, it is possible to achieve a uniform thermal process by uniformly spraying the atomic species in the radical state into a plasma chamber through an improved supply port.

### DESCRIPTION OF DRAWING

The above and other objects, features and other advantages of the present invention will be more clearly understood from the following detailed description taken in conjunction with the accompanying drawings, in which:

FIG. 1 is a diagram illustrating a plasma rapid thermal process apparatus according to an embodiment of the present invention;

FIG. 2 is a diagram illustrating a supply port 160 which is a characteristic part of the present invention; and

FIG. 3 is a diagram illustrating a spray angle (θ) of process gas in a radical state.

### BEST MODE

Hereinafter, a preferred embodiment of the present invention will be described with reference to the accompanying drawings. The preferred embodiment is presented only for understanding of the present invention and those skilled in the art will appreciate that various modifications, additions and substitutions are possible, without departing from the scope and spirit of the invention. Accordingly, the preferred embodiment should not be construed as limiting the present invention.

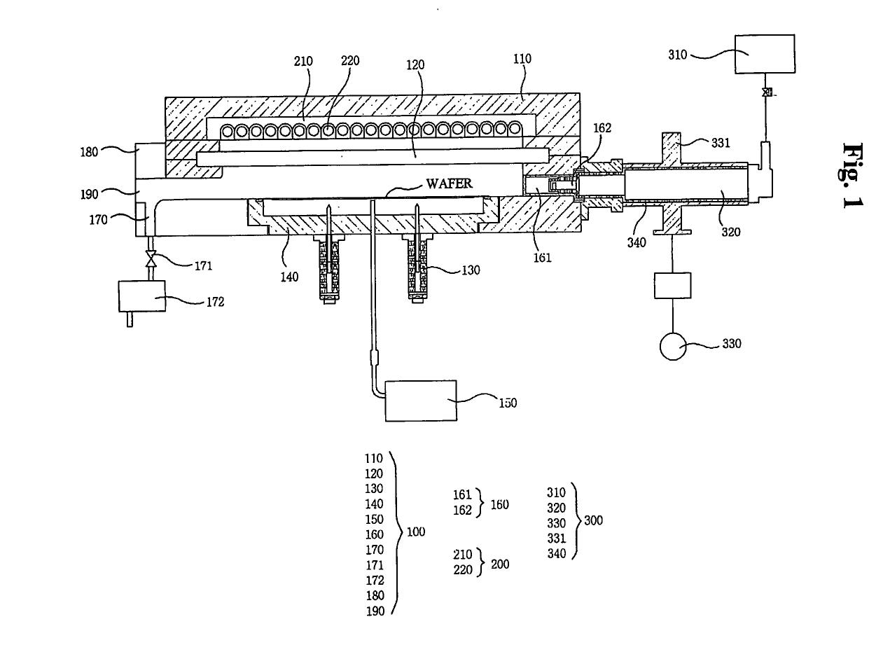

FIG. 1 is a diagram illustrating a plasma rapid thermal process apparatus according to an embodiment of the present invention. Referring to FIG. 1, a process chamber 100 includes a body 110 for providing a space within which a thermal process is performed, a quartz window 120 located beneath a thermal source 200 for separating a region where a plurality of infrared lamps 220 of the thermal source is installed and heat radiated from the plurality of infrared lamps 220 is penetrated from a region where a wafer is mounted, a lift module 130, a wafer support 140 on which the wafer is mounted, and a pyrometer 150 for detecting and controlling temperature.

The process chamber 100 has an inner surface having high reflectivity such that light emitted from the infrared lamps 220 of the thermal source 200 can be reflected and concentrated on the wafer uniformly, and a cooling water path (not shown) for preventing a rise in temperature.

A supply port 160 and an exhaust port 170 for supplying and exhausting the process gas in a radical state, respectively, are formed in the body 110 of the process chamber 100. Both side inner walls of the body 110 are symmetrical on the basis of a virtual line connecting the supply port 160 and the exhaust port 170 each other.

The wafer support 140 is placed within a stepped groove in the bottom of the body 110 such that the top surface of the wafer is parallel with the bottom of the body 110, thereby achieving stable and uniform radiation without having a significant effect on flow of a fluid. A pressure control valve 171 and a vacuum pump 172 are arranged at the exhaust port 170 in order to adjust discharge conditions and pressure of atomic species in a radical state.

An exhaust plate 180 is arranged on a side wall opposite to the supply port 160 so that gas is uniformly exhausted and introduction of air from the outside into the body 110 is minimized. A wafer transfer port 190 and the exhaust port 170 are arranged at the exhaust plate 180. The cooling water path (not shown) is formed on the inner wall of the exhaust plate 180.

The thermal source 200 includes a body 210, the infrared lamps 220, and the cooling water path (not shown). The infrared lamps 220 form concentric circles having different radiuses and are arranged in a reflection surface groove of the body 210 such that light emitted from each of the infrared lamps 220 minutely overlaps and radiation heat is uniformly reflected from the entire top surface of the wafer. The cooling water path is formed within the body 210 such that cooling water flows around the reflection surface groove. In addition, a cooling air injection path (not shown) for rapid temperature reduction and an exhaust path (not shown) for compulsory exhaustion of air are also formed at the body 210. In addition, a cooling water plate (not shown) for reducing the high temperature of the exhaust gas is formed at the exhaust path.

A plasma supply apparatus 300 includes a gas supply module 310 for controlling supply and flow of gas, the discharge tube 320 made of quartz or sapphire and defining the supply port 160 and a discharge region, a waveguide 331 enclosing the discharge tube 320, and a microwave supply apparatus 330 for supplying microwaves at a frequency of 2.45 GHz to the discharge tube 320.

Process gas supplied from the gas supply module 310 is plasmalized and excited into a radical state by the microwaves while passing through the discharge tube 320. Then, the process gas consisting of atomic radicals is supplied into the process chamber 100 through the supply port 160. More than one gas selected from the group consisting of N₂, O₂, H₂, N₂O, NO, NO₂, Ar, NH₃, O₃, etc., according to the purpose of thermal process, are supplied through the gas supply module 310.

Since the process gas in the radical state, which is excited in the discharge tube 320, is apt to be recombined to some degree although the degree of recombination depends on the kind of gas, and process efficiency may be deteriorated due to ununiform flow of gas in the chamber, a separate arrangement for avoiding this is required.

For example, first, a heating apparatus 340 for heating a region defining a flow path of the process gas in the radical state, i.e., a rear stage of the discharge tube 320, is provided to maintain the region above the temperature at which recombination of the process gas in the radical state can occur. A heating pad can be used as the heating apparatus 340. Although recombination rate of the process gas depends on the kind of gas, it is linearly decreased in the range of room temperature to 100° C. and is saturated at above 100° C.

Second, the region defining the flow path of the process gas in the radical state is made of a material with a low surface recombination rate, such as quartz, Teflon, alumina, aluminum 6061, ST 304, and Hastelloy C-22, or a material coated with Teflon. In this case, the flow path of the process gas is preferably made of alumina or quartz.

Third, in order to minimize the recombination rate of the process gas in the radical state, it is necessary to minimize the length of the flow path of the process gas in the radical state. To this end, the length of the supply port 160 is preferably the same as the thickness of the side wall of the chamber 100 in the case that the plasma supply apparatus 300 is directly connected to the supply port 160, and the length of the flow path of the process gas in the radical state is preferably less than 100 mm in the case that the plasma supply apparatus 300 is connected to the supply port 160 through a separate connector. Although an optimal process is obtained experimentally when the inner diameter of the supply port 160 is 15 to 25 mm, it is not limited to this, but can be changed depending on process conditions.

The three arrangements as described above may be used individually or in combination. Although optimal use power of the microwave supply apparatus 330 is related to the kind, the amount of flow, and pressure of the process gas, a resolution rate adapted to a process with the above described conditions can be obtained using a power of less than 3 KW.

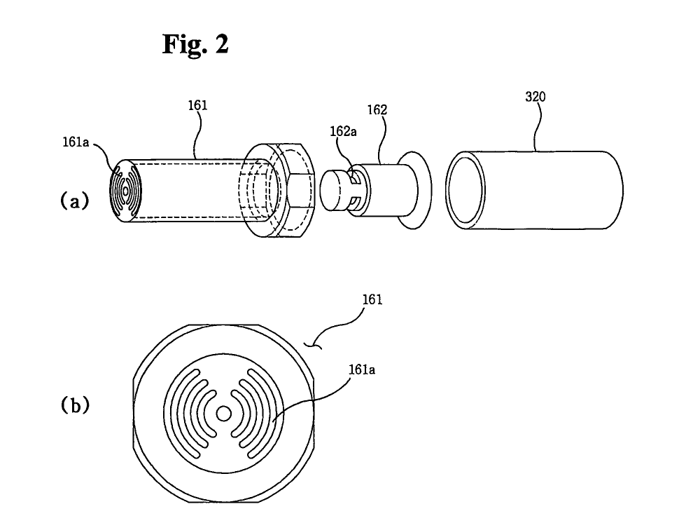

FIG. 2 is a diagram illustrating a supply port 160 which is a characteristic part of the present invention. The pressure of the process gas in the radical state may be ununiform when the process gas is sprayed into the chamber 100. To prevent this ununiformity, the supply port 160 of the present invention has a configuration where the gas is buffered to some degree and then sprayed.

The supply port 160 includes an inner tube 162 and an outer tube 161. The inner tube 162 has one end which is opened and connected to the discharge tube 320 and the other end which is closed. The diameter of a closed portion of the other end is smaller than those of other portions of the other end. A first spray hole 162a is formed around a side wall of the closed portion. The outer tube 161 has one end which is opened such that the closed portion of the inner tube 162 is inserted in the one end, and the other end at which a plurality of second spray holes 161a is formed. The other end of the outer tube 161 is spaced apart by a predetermined interval from the other closed end of the inner tube 162.

Accordingly, radical atomic species are sprayed toward the side wall of the outer tube 161 through the first spray hole 162a. The process gas in the radical state, which is sprayed through the first spray hole 162a, is mixed in a space between the inner tube 162 and the outer tube 161 so that uniformity of pressure of the process gas can be attained, and then, is sprayed toward the outside through the second spray holes 161a. Thus, uniform spray of the process gas can be attained, and accordingly, the process gas in the radical state flows with a lamina form in an internal region of the process chamber.

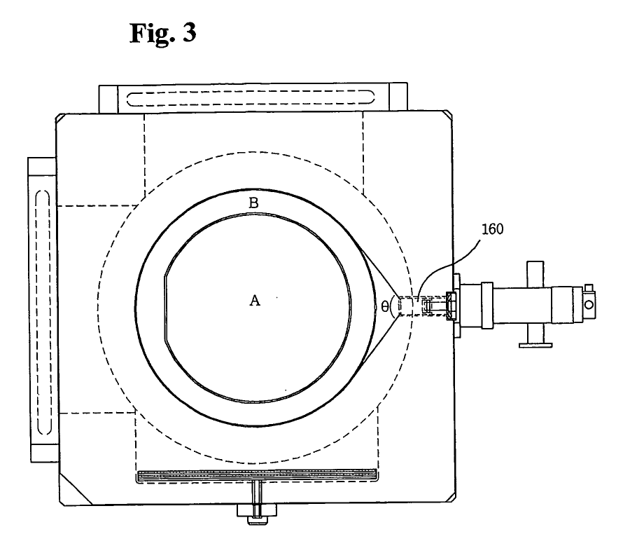

FIG. 3 is a diagram illustrating a spray angle (θ) of process gas in a radical state. It is preferable that the infrared lamps 220 and the supply port 160 are appropriately arranged such that a radiation region of light emitted from the infrared lamps 220 coincides with a spray region of a radical source sprayed from the supply port 160. In this case, a spray angle (θ) of the process gas sprayed through the second spray holes 161a of the supply port 160 is preferably large enough that the spray region (B) of the process gas covers the entire area (A) of the wafer. To this end, the second spray holes 161 are inclined to some degree toward the outside.

Although the process chamber has been described as having one supply port and one exhaust port in the preferred embodiment, it is not limited to this, rather, the process chamber can have a plurality of supply ports and a plurality of exhaust ports in a one to one correspondence way. In the case of the plurality of supply ports, the plasma supply apparatus need not be provided at all the supply ports. In addition, raw process material of a general form of gas rather than a radical form of gas can be supplied through the supply port to which the plasma supply port is not connected.

Although the preferred embodiment of the present invention has been disclosed for illustrative purposes, those skilled in the art will appreciate that various modifications, additions and substitutions are possible, without departing from the scope and spirit of the invention as disclosed in the accompanying claims.

1. A plasma rapid thermal process apparatus comprising a chamber having a supply port and an exhaust port provided at both ends thereof, with a wafer being mounted in the chamber, a thermal source provided in the chamber and including a plurality of lamps for heating the wafer, a gas supply module for supplying process gas, a discharge tube for plasmalizing the process gas supplied from the gas supply module, and a microwave supply apparatus for supplying microwaves to the discharge tube,
wherein the supply port supplies atomic radicals to the chamber, the radicals being formed by the plasmalization of the process gas in the discharge tube, and
wherein the supply port includes:
an inner tube having one end which is opened and connected to the discharge tube and the other end which is closed, the diameter of a closed portion of the other end being smaller than those of other portions of the other end, and a first spray hole being formed around a side wall of the closed portion; and
an outer tube having one end which is opened such that the closed portion of the inner tube is inserted in the one end, and the other end at which a plurality of second spray holes is formed, the other end of the outer tube being spaced apart by a predetermined interval from the other closed end of the inner tube.

2. The plasma rapid thermal process apparatus as set forth in claim 1, wherein the supply port and the exhaust port are arranged at side walls of the chamber, the inside of the chamber is symmetrical on the basis of a virtual line connecting the supply port and the exhaust port, and the bottom of the chamber is formed in parallel with the wafer.

3. The plasma rapid thermal process apparatus as set forth in claim 1, wherein a heating apparatus is arranged around the supply port.

4. The plasma rapid thermal process apparatus as set forth in claim 1, wherein the inner and outer tubes of the supply port are made of quartz, Teflon, alumina, aluminum 6061, ST 304, or Hastelloy C-22, or inner surfaces of the inner and outer tubes are coated with Teflon.

5. The plasma rapid thermal process apparatus as set forth in claim 1, wherein the length of the supply port is greater than the thickness of the side wall of the chamber and is less than 100 mm.

6. The plasma rapid thermal process apparatus as set forth in claim 1, wherein, the inner diameter of the supply port is 15 to 25 mm.

7. The plasma rapid thermal process apparatus as set forth in claim 1, wherein at least two supply ports and at least two exhaust ports are oppositely arranged in a one-to-one correspondence in the chamber, and at least one supply port is connected to the plasma supply apparatus.

8. The plasma rapid thermal process apparatus as set forth in claim 1, wherein an exhaust plate on which a cooling water path is formed is arranged on a side wall opposite to the side wall on which the supply port is provided, a wafer transfer port and the exhaust port being arranged at the exhaust plate 180.

9. The plasma rapid thermal process apparatus as set forth in claim 1, wherein the lamps of the thermal source are provided to emit light in a downward direction of the lamps and the supply port is arranged such that the process gas in the radical state is sprayed in parallel with the wafer within the chamber, and the lamps and the supply port are arranged such that a radiation region of light emitted from the lamps and a spray region of the process gas coincide with each other above the wafer.

10. The plasma rapid thermal process apparatus as set forth in claim 1, wherein a discharge pressure control valve and a vacuum pump are arranged at the exhaust port.

11. The plasma rapid thermal process apparatus as set forth in claim 1, wherein a spray angle of the supply port is formed such that the spray region of atomic radicals supplied through the supply port covers the entire wafer.
